(19) United States
(12) Patent Application Publication
(10) Pub. No.: US 2016/0035723 A1
(43) Pub. Date: Feb. 4, 2016

(54) MACRO DESIGN OF DEVICE CHARACTERIZATION FOR 14NM AND BEYOND TECHNOLOGIES

(71) Applicant: GLOBALFOUNDRIES Inc., Grand Cayman (KY)

(72) Inventors: Xusheng WU, Ballston Lake, NY (US); Yanxiang LIU, Glenville, NY (US)

(21) Appl. No.: 14/447,193

(22) Filed: Jul. 30, 2014

(51) Int. Cl. H01L 27/088; H01L 21/8234; H01L 29/45; H01L 21/66

(52) U.S. Cl. CPC H01L 27/0886; H01L 22/14; H01L 21/823431; H01L 21/823437; H01L 29/456

(57) ABSTRACT

The disclosure provides methods and devices for separately determining the channel resistance and the extension resistance of a FinFET. An exemplary embodiment includes forming first and second fins parallel to each other, forming at least one fin portion, connecting the first and second fins, forming a gate perpendicular to the first and second fins, over the at least one fin portion, forming a first source and a first drain over the first fin at opposite sides of the gate, and forming a second source and a second drain over the second fin, separate from the first source and drain, at opposite sides of the gate, wherein each of the first and second sources and first and second drains includes an extension region.

### TECHNICAL FIELD

The present disclosure relates to fin-type field-effect transistors (FinFETs). In particular, the present disclosure relates to methods and devices for determining the channel resistance (Rch) and extension resistance (Rex) of a FinFET.

### BACKGROUND

FIG. 1 illustrates a simplified cross-sectional view of a metal oxide semiconductor field-effect transistor (MOSFET) 101, which may be formed on a semiconductor silicon substrate 103 between shallow trench isolation (STI) regions 105 filled with a dielectric material such a silicon dioxide (SiO₂). The silicon substrate 103 includes a source 107 with an extension region 109, a channel region 111, and a drain 113 also with an extension region 115. All of these regions are formed of one or more n-type or p-type doped semiconductor materials. The channel region 111 is covered on the top by a gate dielectric, such as SiO₂ and/or high-κmaterial (not shown) and a gate electrode 117. Adjacent opposite sides of the gate electrode 117 are spacers 119. The gate electrode 117 is surrounded by an interlayer dielectric (ILD) 121, such as SiO₂, through which a trench silicide/contact area (TS/CA) 123 is formed over each of source 107 and drain 113. When switched on, the gate electrode 117 provides a path (conducting channel) in the channel region 111 for current to flow. The on resistance (Ron) of the device can be calculated from the sum of the resistances in the channel region, the extension regions, and the TS/CA regions of the source and drain.

FIG. 2 illustrates a simplified top view perspective of a fin field-effect transistor (FinFET) 201, which may also be formed on a semiconductor silicon substrate (not shown). The device includes a first fin 203 and a second fin 205, which are parallel to each other. Over the first and second fins are a first source 207 and a first drain 209, and a second source 211 and a second drain 213, respectively, with a gate electrode 217 covering the two fins between the sources and the drains. Each of the first and second sources and the first and second drains also includes an extension region (not shown). Also shown are separate dummy gates 215, separated from gate electrode 217 by TS/CA regions 219.

The various parts making up FinFET 201 as described above and shown in FIG. 2, including the first and second fins, first and second sources, first and second drains, gate electrode, dummy gates, TS/CA regions and others, are shown for illustrative purposes only. Various modifications and changes to the sizes and dimensions of these parts may be made by those of skill in the art.

For a conventional FET device as shown in FIGS. 1 and 2, Ron is given by equation I:

Ron=2Rch+2Rex+2Rcon (I),

where Rch is the resistance of half of the length of the conducting channel; Rex is the resistance of the extension regions; and Rcon is the resistance of the TS/CA regions. The multiplier “2” is used before each of the variables in equation I because the device has a symmetrical structure. More specifically, the source and drain extension regions and the TS/CA regions are symmetrical about the gate electrode (i.e., there is one of each on each side of the gate electrode) and therefore, the values for Rex and Rcon are multiplied by 2. Since Rch is defined as the resistance of half of the length of the conducting channel, the value of Rch is also multiplied by 2 in equation I to calculate the total Ron of the device.

It is empirically known that Ron is a function of the length of the conducting channel. However, for short channel devices, such as for the 14 nanometer (nm) technology node and beyond, this relationship frequently fails due to parasitic components impacting Rex, short channel device mobility degradation, and mismatched over drive in Ron measurement due to short channel effect. Rcon can be found using Kelvin probe force microscopy, however, Rch and Rex are always combined together in one gate length. As FinFET devices are scaled down to include more transistors in accordance with Moore's law, the value of the Rex of the device becomes important in evaluating its performance, particularly for short channel devices. Methods and devices for decoupling the values of Rch and Rex may lead to FinFET devices with better characterization and further better device design induced performance improvement. Further modifications of these structures, accordingly, are needed to meet the increasing goals of the industry.

A need therefore exists for methodology enabling the decoupling of Rch and Rex for increasing the performance of FinFET devices.

### SUMMARY

An aspect of the present disclosure is a method of forming a FinFET having first and second fins parallel to each other and connected with at least one fin portion.

Another aspect of the present disclosure is a FinFET device having first and second fins parallel to each other and connected with at least one fin portion.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming first and second fins parallel to each other; forming at least one fin portion, connecting the first and second fins; forming a gate perpendicular to the first and second fins, over the at least one fin portion; forming a first source and a first drain over the first fin at opposite sides of the gate; and forming a second source and a second drain over the second fin, separate from the first source and drain, at opposite sides of the gate, wherein each of the first and second sources and first and second drains includes an extension region.

Aspects of the present disclosure also include forming the at least one fin portion, connecting the first and second fins, by forming a single fin portion perpendicular to the first and second fins.

Further aspects of the present disclosure include determining a resistance of the first and second source and first and second drain extension regions utilizing two test modes, a first mode in which the on resistance (Ron1) satisfies Ron1=2 (Rex+Rch), and the second mode in which the on resistance (Ron2) satisfies Ron2=2 (Rex +Rch)+Rint, wherein Rch is the gate channel resistance, and Rint is the internal resistance along the fin portion.

Still further aspects of the present disclosure include for each of the test modes, the gate voltage (Vg) equals the power supply voltage (Vdd), the first drain voltage (Vd1) equals 0.05 V, and the set of voltages for the first source (Vs1), the second source (Vs2), and the second drain (Vd2) for the first test mode differs from the set of voltages for the Vs1, Vs2, and Vd2 for the second test mode.

Additional aspects of the present disclosure include for each of the two test modes, Vs1 equals 0 V, and Vd2 and Vs2 are floating for the first test mode; and Vs2 equals 0 V, and Vs1 and Vd2 are floating for the second test mode.

Other aspects of the present disclosure include a method, wherein the first fin includes first and second fin sections separated from each other, and the second fin includes first and second fin sections separated from each other, and forming the at least one fin portion including: forming a first fin portion connecting the first fin section of the first fin and the second fin section of the second fin; forming a second fin portion crossing the first fin portion, connecting the second fin section of the first fin and the first fin section of the second fin; and forming a third fin portion, in a v-shape, connecting the first fin section of the second fin and the second fin section of the second fin.

Further aspects of the present disclosure include determining a resistance of the first and second source and first and second drain extension regions utilizing two test modes, a first mode in which the on resistance (Ron1) satisfies Ron1=3/2 (Rch+Rex), and the second mode in which the on resistance (Ron2) satisfies Ron2=Rch+2 Rex, wherein Rch equals the gate channel resistance.

Still further aspects of the present disclosure include a method wherein for each of the test modes, the gate voltage (Vg) equals the power supply voltage (Vdd) and the first drain voltage (Vd1) equals 0.05 V, and the set of voltages for the first source (Vs1), and the second source (Vs2), and the second drain (Vd2) for the first test mode differs from the set of voltages for the Vs1, Vs2, and Vd2 for the second test mode.

Additional aspects of the present disclosure include a method wherein Vs1 equals 0 V, and Vd2 and Vs2 are floating for the first test mode; and Vs2 equals 0 V, and Vs1 and Vd2 are floating for the second test mode.

Another aspect of the present disclosure includes a device having: first and second fins parallel to each other; at least one fin portion, connecting the first and second fins; a gate perpendicular to the first and second fins, over the at least one fin portion; a first source and a first drain over the first fin at opposite sides of the gate; and a second source and a second drain over the second fin, separate from the first source and drain, at opposite sides of the gate, wherein each of the first and second sources and first and second drains includes an extension region.

Further aspects of the present disclosure include a device wherein the at least one fin portion includes a single fin portion perpendicular to the first and second fins.

Still further aspects of the present disclosure include a device, wherein the first fin includes first and second fin sections separated from each other, and the second fin includes first and second fin sections separated from each other, and the at least one fin portion includes: a first fin portion connecting the first fin section of the first fin and the second fin section of the second fin; a second fin portion crossing the first fin portion, connecting the second fin section of the first fin and the first fin section of the second fin; and a third fin portion, in a v-shape, connecting the first fin section of the second fin and the second fin section of the second fin.

Additional aspects of the present disclosure include a device, and further include a first dummy gate over the first and second fins, adjacent the first and second drains, opposite the gate; and a second dummy gate over the first and second fins, adjacent the first and second sources, opposite the gate.

Other additional aspects of the present disclosure include a device, and further include a first TS/CA contact over the first source and first drain over the first fin at opposite sides of the gate; and second TS/CA contact over the second source and second drain over the second fin at opposite sides of the gate.

Other aspects of the present disclosure include a method of: forming a plurality of pairs of first and second fins on a silicon substrate, the first and second fins being parallel to each other; forming at least one fin portion, connecting the first and second fins for each pair of first and second fins; forming a gate perpendicular to the plurality of pairs of first and second fins and over each at least one fin portion; forming a first source and a first drain over each first fin at opposite sides of the gate; and forming a second source and a second drain over each second fin, separate from the first source and drain, at opposite sides of the gate, wherein each of the first and second sources and first and second drains includes an extension region.

Aspects of the present disclosure also include determining a resistance of the first and second source and first and second drain extension regions (Rex) utilizing two test modes, a first mode in which the on resistance (Ron1) satisfies Ron1=2 (Rex+Rch), and the second mode in which the on resistance (Ron2) satisfies Ron2=2 (Rex+Rch)+Rint, wherein Rch is the gate channel resistance, and Rint is the internal resistance along the fin portion.

Other aspects of the present disclosure include a method, wherein each first fin includes first and second fin sections separated from each other, and each second fin includes first and second fin sections separated from each other, and forming each at least one fin portion includes: forming a first fin portion connecting the first fin section of the first fin and the second fin section of the second fin; forming a second fin portion crossing the first fin portion, connecting the second fin section of the first fin and the first fin section of the second fin; and forming a third fin portion, in a v-shape, connecting the first fin section of the second fin and the second fin section of the second fin.

Further aspects of the present disclosure include determining a resistance of the first and second source and first and second drain extension regions (Rex) utilizing two test modes, a first mode in which the on resistance (Ron1) satisfies Ron1=3/2 (Rch+Rex), and the second mode in which the on resistance (Ron2) satisfies Ron2=Rch+2 Rex, wherein Rch equals the gate channel resistance.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 illustrates a cross-sectional view of a conventional MOSFET;

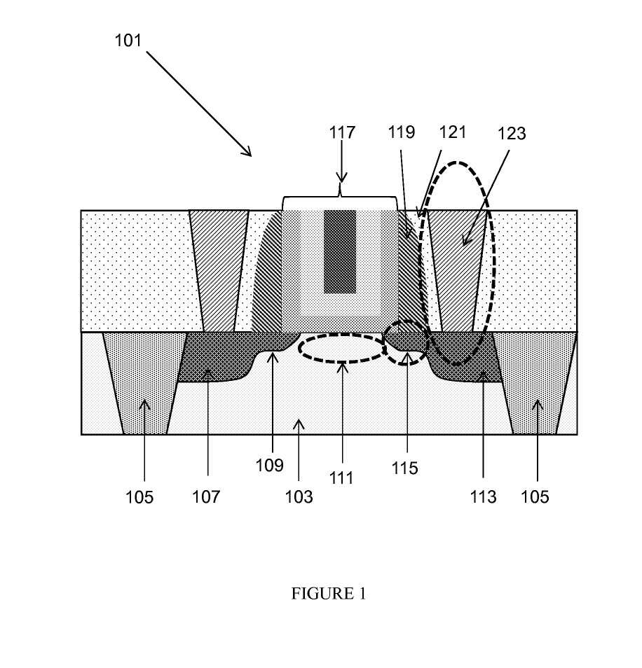

FIG. 2 illustrates a simplified top cut-away view of a conventional FinFET;

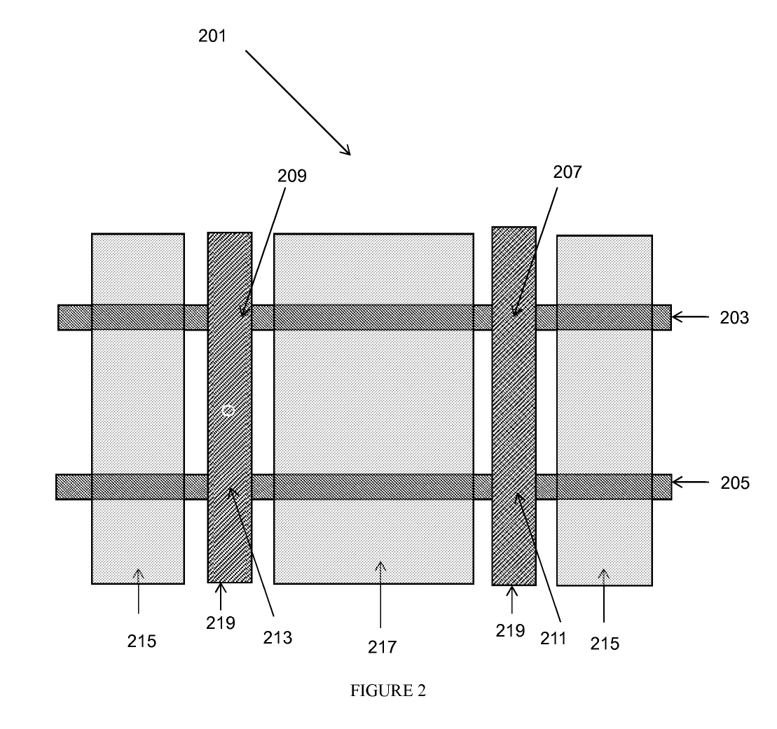

FIG. 3 illustrates a simplified top cut-away view of a multi-gate FinFET device in accordance with an exemplary embodiment;

FIG. 4 illustrates a pathway for current to flow through a FinFET in accordance with the exemplary embodiment of FIG. 3;

FIG. 5 illustrates an alternative pathway for current to flow through a FinFET in accordance with the exemplary embodiment of FIG. 3;

FIG. 6 illustrates a simplified top cut-away view of a multi-gate FinFET device in accordance with another exemplary embodiment;

FIG. 7 illustrates a pathway for current to flow through a FinFET in accordance with the exemplary embodiment of FIGS. 6; and

FIG. 8 illustrates an alternative pathway for current to flow through a FinFET in accordance with the exemplary embodiment of FIG. 6.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of a need to but an inability to decouple the values for Rch and Rex and determine the value for Rex attendant upon scaling down FinFET devices. The methods for decoupling these values may lead to FinFET devices with better characterization and further better device design induced performance improvement.

Methodology in accordance with embodiments of the present disclosure include forming at least two STI regions, filled with dielectric material, adjacent to but separate from each other in a silicon substrate. First and second fins are then formed parallel to each other between two STI regions. Next, at least one fin portion is formed that connects the first and second fins. A gate is then formed perpendicular to the first and second fins and over the at least one fin portion that connects the first and second fins. A first source and a first drain are formed over the first fin at opposite sides of the gate. A second source and a second drain are also formed over the second fin, separate from the first source and drain, at the opposite sides of the gate. Each of the first and second sources and first and second drains include an extension region.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

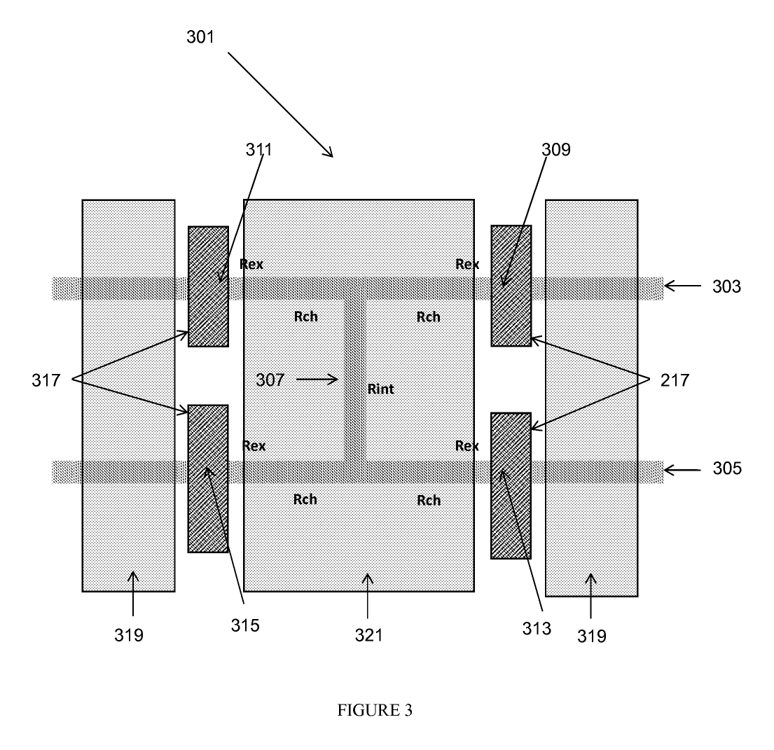

FIG. 3 illustrates a simplified top cut-away view of a multi-gate FinFET 301 according to an exemplary embodiment. The device includes a first fin 303 and a second fin 305, which are parallel to each other; and a fin portion 307, which connects the first and second fins to form a fallen H-like structure. In this structure, Rch is the resistance of the channel in the first and second fins; and Rint is the resistance of the internal fin portion. Over the first and second fins are a first source 309 and a first drain 311, and a second source 313 and a second drain 315, respectively, with a gate electrode 321 covering the two fins and the fin portion 307 between the sources and the drains. Each of the first and second sources and the first and second drains also includes an extension region (not shown). Rex is the resistance of the extension region. Also shown are separate TS/CA contacts 317 over source regions 309 and 313 and drain regions 311 and 315. The TS/CA contacts 317 separate dummy gates 319 from gate electrode 321.

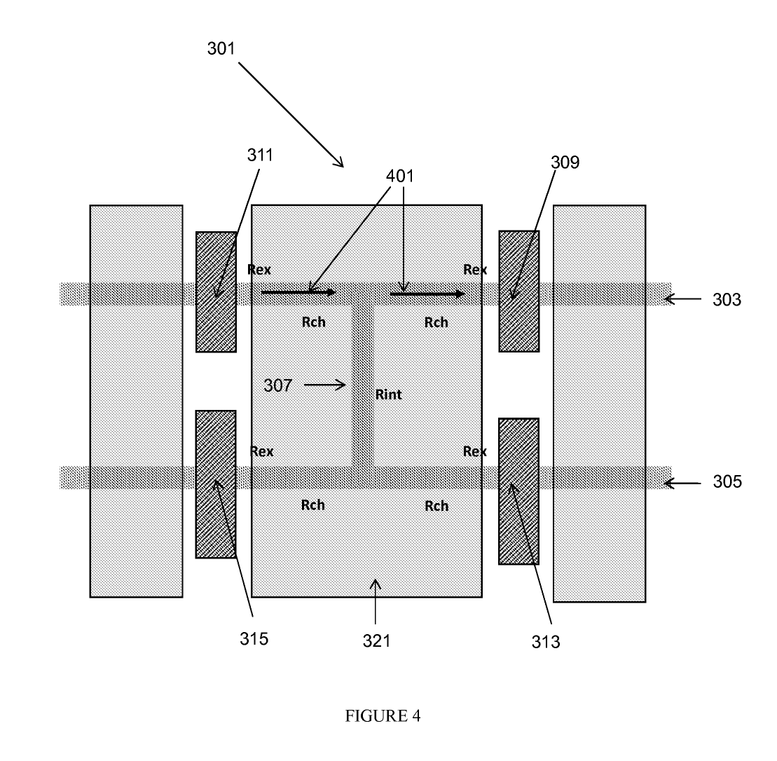

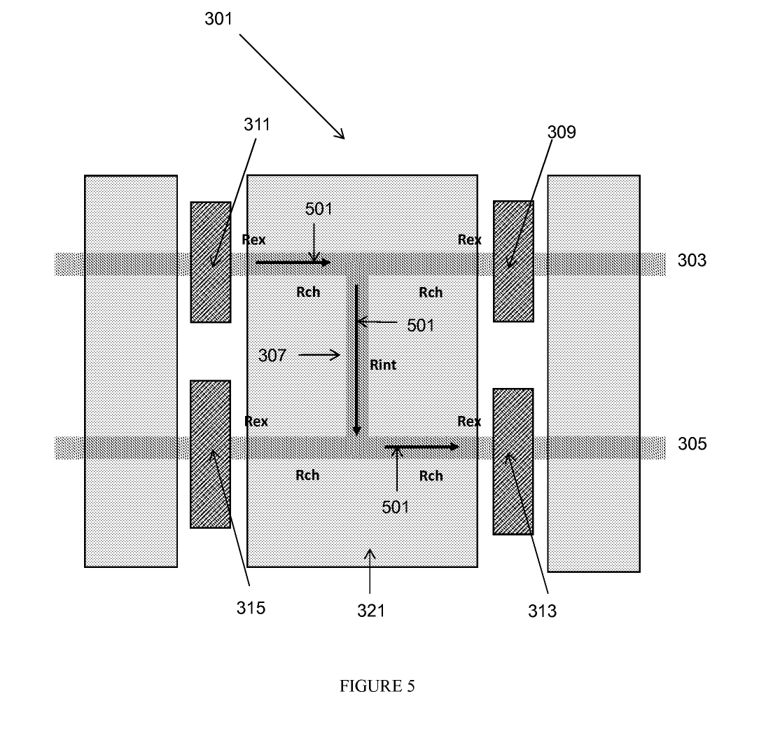

FIGS. 4 and 5 illustrate two pathways for current to flow through the fallen H-like structure in FinFET 301.

In FIG. 4, the flow of current is directly across the first fin 303, represented by arrows 401 (or the second fin 305, not shown). For Test—1: Vg=Vdd, Vs-1=0, Vd-1=0.05, and Vd-2/Vs-2 are floating. The on resistance of the first path (Ron1) can be calculated according to equation II:

Ron1=Rex+Rch+Rch+Rex (II).

Combining terms and simplifying equation II leads to equation III:

Ron1=2(Rex+Rch) (III).

In equation III, the combined value of (Rch+Rex) can be calculated according to equations IV:

(Rex+Rch)=(Ron1)/2 (IV)

However, the values of Rex and Rch cannot be decoupled from each other.

In FIG. 5, an alternative path for the flow of current through the fallen H-like structure in FinFET 301 is shown. In this figure, the flow of current is across the first fin 303, the fin portion 307, and the second fin 305, represented by arrows 501. For Test—2: Vg=Vdd, Vs-2=0, Vd-1=0.05, and Vd-2/Vs-1 are floating, the on resistance of the second path (Ron2) can be calculated according to equation V:

Ron2=Rex+Rch+Rint+Rch+Rex (V).

Combining terms and simplifying equation V leads to equation VI:

Ron2=2(Rex+Rch)+Rint (VI).

Solving for Rint in equation VI leads to equation VII:

Rint=Ron2−2)Rex+Rch) (VII).

Simplifying equation VII by substituting the value of (Rex+Rch) from equation III leads to equation VIII:

Rint=Ron2−Ron1 (VIII).

Thus, Rint can be calculated from the difference between the Ron2 and Ron1.

By using the design length of Rint vs. Rch, Rch can be calculated. For example, the fin regions under the gate for Rint and Rch have the same resistivity per unit length. Therefore, Rint and Rch are proportional to their length according to equation IX:

Rch/Rint=Lch/Lint (IX)

Thus, if Rint is calculated from the difference in Ron2 and Ron 1 according to equation VIII, Rch can be calculated by rearranging terms in equation (IX) to lead to equation (X):

Rch=Rint(Lch/Lint) (X).

Once the value of Rch has been determined, Rex can be calculated by rearranging equation III to equation XI:

Rex=(Ron1)/2−Rch (XI).

Alternatively, Rex can be calculated by rearranging equation VI to equation XII:

Rex=(Ron2−Rint)/2−Rch (XII).

Accordingly, the values for Rch and Rex in FinFET 301 may be decoupled and calculated independently of each other.

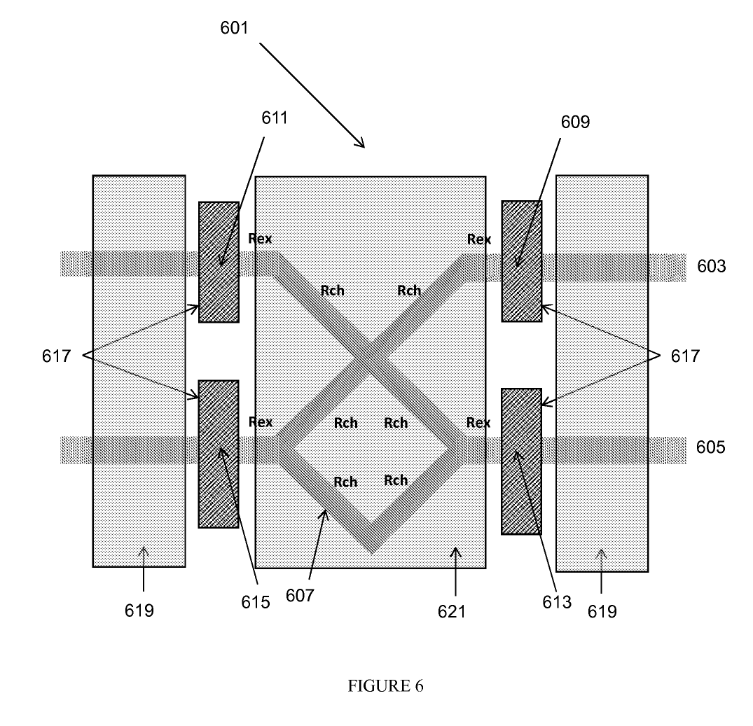

In another exemplary embodiment, FIG. 6 illustrates a simplified top cut-away view of an alternative multi-gate FinFET 601. The device includes a first fin 603 and a second fin 605, which are interconnected in a lattice like structure including a v-shaped fin loop portion 607. In this structure, Rch is the resistance of the channel in the first and second fins and the v-shaped fin loop portion. Over the first and second fins are a first source 609 and a first drain 611, and a second source 613 and a second drain 615, respectively, with a gate electrode 621 between the sources and the drains and covering the connecting portions of the fins. Each of the first and second sources and the first and second drains also includes an extension region (not shown). Rex is the resistance of the extension regions. Also shown are separate TS/CA contacts 617 separating dummy gates 619 from gate electrode 621.

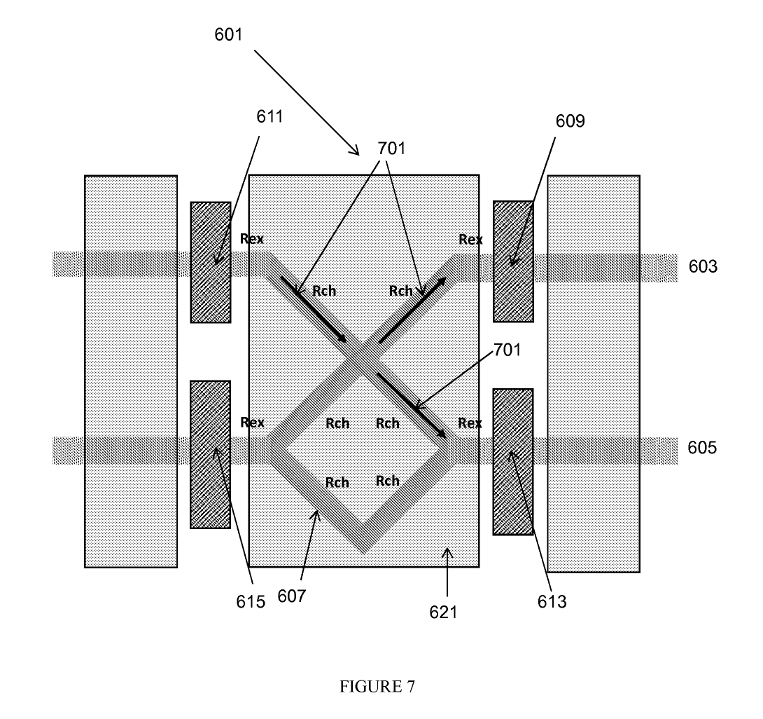

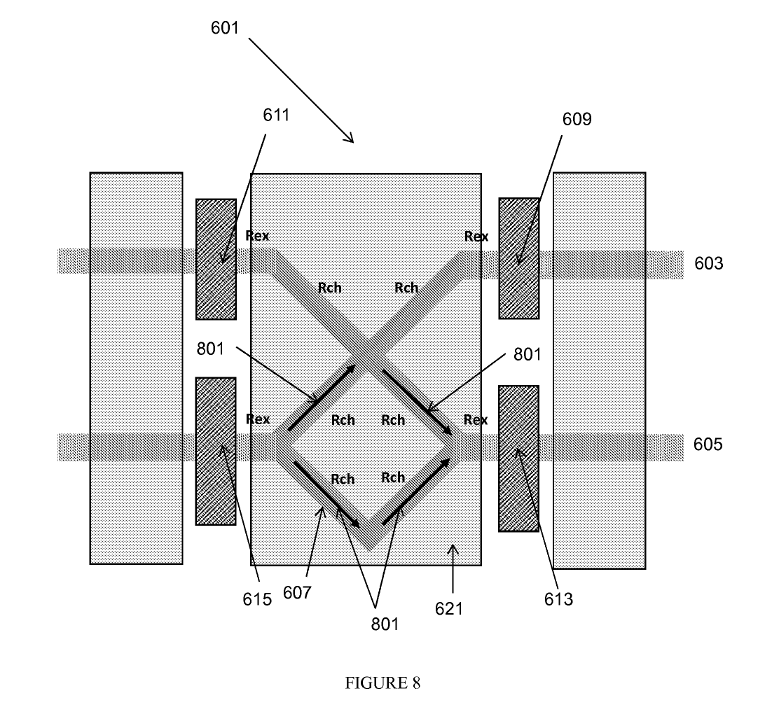

FIGS. 7 and 8 illustrate two pathways for current to flow through the lattice-like structure of FinFET 601.

In FIG. 7, the flow of current is across the first fin 603 and also across to the second fin 605, as represented by arrows 701. For Test—1: Vg=Vdd, Vs-1=Vs-2=0, Vd-1=0.05, and Vd-2 is floating. The on resistance of the first path (Ron1) can be calculated according to equation XIII:

Ron1=Rex+Rch+(Rch+Rex)//(Rch+Rex) (XIII).

Combining terms and simplifying equation XI leads to equation XIV:

Ron1=3/2Rch+Rex) (XIV).

In equation XIV, the combined value of (Rch+Rex) can be extracted according to equations XV:

(Rex+Rch)=2/3(Ron1) (XV).

However, the values of Rex and Rch cannot be decoupled from each other.

In FIG. 8, an alternative path for the flow of current through the lattice-like structure in FinFET 601 is shown. In this figure, the flow of current is across the second fin 605 and also across the fin loop portion 607, as represented by arrows 801. For Test—2: Vg=Vdd, Vs-2=0, Vd-2=0.05, and Vd-1/Vs-1 are floating. The on resistance of the second path (Ron2) can be calculated according to equation XVI:

Ron2=Rex+(Rch+Rch)//(Rch+Rch)+Rex (XVI).

Combining terms and simplifying equation XIV leads to equation XVII:

Ron2=Rch+2Rex (XVII).

Using equations XIV and XVII and solving for Rex leads to equation XVIII:

Rex=Ron2−2/3Ron1 (XVIII).

Using equations XIV and XVII and solving for Rch leads to equation XIX:

Rch=4/3Ron1−Ron2 (XIX).

Accordingly, the values for Rex and Rch in FinFET 601 may be decoupled and calculated independently of each other.

The embodiments of the present disclosure can achieve several technical effects, such as providing methods and devices for separately determining the resistance of the channel and the resistance of the extension regions, without complicated and expensive processes of fabrication. Devices formed in accordance with embodiments of the present disclosure are useful in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore has industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
forming first and second fins parallel to each other;
forming at least one fin portion, connecting the first and second fins;
forming a gate perpendicular to the first and second fins, over the at least one fin portion;
forming a first source and a first drain over the first fin at opposite sides of the gate;
forming a second source and a second drain over the second fin, separate from the first source and drain, at opposite sides of the gate; and
determining a resistance of the first and second source and first and second drain extension regions (Rex) utilizing two test modes, a first mode in which the on resistance (Ron1) satisfies Ron1=2 (Rex+Rch), and the second mode in which the on resistance (Ron2) satisfies Ron2=2 (Rex+Rch)+Rint, wherein Rch is the gate channel resistance, and Rint is the internal resistance along the fin portion,
wherein each of the first and second sources and first and second drains includes an extension region, and
wherein forming the at least one fin portion comprises forming a single fin portion perpendicular to the first and second fins.

2. (canceled)

3. (canceled)

4. The method according to claim 1, wherein for each of the test modes, the gate voltage (Vg) equals the power supply voltage (Vdd), the first drain voltage (Vd1) equals 0.05 V, and the set of voltages for the first source (Vs1), the second source (Vs2), and the second drain (Vd2) for the first test mode differs from the set of voltages for the Vs1, Vs2, and Vd2 for the second test mode.

5. The method according to claim 4, wherein Vs1 equals 0 V, and Vd2 and Vs2 are floating for the first test mode; and Vs2 equals 0 V, and Vs1 and Vd2 are floating for the second test mode.

6. The method according to claim 1, wherein the first fin comprises first and second fin sections separated from each other, and the second fin comprises first and second fin sections separated from each other, and forming the at least one fin portion comprises:
forming a first fin portion connecting the first fin section of the first fin and the second fin section of the second fin;
forming a second fin portion crossing the first fin portion, connecting the second fin section of the first fin and the first fin section of the second fin; and
forming a third fin portion, in a v-shape, connecting the first fin section of the second fin and the second fin section of the second fin.

7. The method according to claim 6, further comprising determining a resistance of the first and second source and first and second drain extension regions (Rex) utilizing two test modes, a first mode in which the on resistance (Ron1) satisfies Ron1=3/2(Rch+Rex), and the second mode in which the on resistance (Ron2) satisfies Ron2=Rch+2 Rex, wherein Rch equals the gate channel resistance.

8. The method according to claim 7, wherein for each of the test modes, the gate voltage (Vg) equals the power supply voltage (Vdd) and the first drain voltage (Vd1) equals 0.05 V, and the set of voltages for the first source (Vs1), and the second source (Vs2), and the second drain (Vd2) for the first test mode differs from the set of voltages for the Vs1, Vs2, and Vd2 for the second test mode.

9. The method according to claim 8, wherein Vs1 equals 0 V, and Vd2 and Vs2 are floating for the first test mode; and Vs2 equals 0 V, and Vs1 and Vd2 are floating for the second test mode.

10. A device comprising:
first and second fins parallel to each other;
at least one fin portion, connecting the first and second fins;
a gate perpendicular to the first and second fins, over the at least one fin portion;
a first source and a first drain over the first fin at opposite sides of the gate; and
a second source and a second drain over the second fin, separate from the first source and drain, at opposite sides of the gate,
wherein each of the first and second sources and first and second drains includes an extension region.

11. The device according to claim 10, wherein the at least one fin portion comprises a single fin portion perpendicular to the first and second fins.

12. The device according to claim 10, wherein the first fin comprises first and second fin sections separated from each other, and the second fin comprises first and second fin sections separated from each other, and the at least one fin portion comprises:
a first fin portion connecting the first fin section of the first fin and the second fin section of the second fin;
a second fin portion crossing the first fin portion, connecting the second fin section of the first fin and the first fin section of the second fin; and
a third fin portion, in a v-shape, connecting the first fin section of the second fin and the second fin section of the second fin.

13. The device according to claim 12, further comprising a first dummy gate over the first and second fins, adjacent the first and second drains, opposite the gate; and a second dummy gate over the first and second fins, adjacent the first and second sources, opposite the gate.

14. The device according to claim 11, further comprising a first dummy gate over the first and second fins, adjacent the first and second drains, opposite the gate; and a second dummy gate over the first and second fins, adjacent the first and second sources, opposite the gate.

15. The device according to claim 11, further comprising a first TS/CA contact over the first source and first drain over the first fin at opposite sides of the gate; and second TS/CA contact over the second source and second drain over the second fin at opposite sides of the gate.

16. The device according to claim 12, further comprising a first TS/CA contact over the first source and first drain over the first fin at opposite sides of the gate; and second TS/CA contact over the second source and second drain over the second fin at opposite sides of the gate.

17. A method comprising:
forming a plurality of pairs of first and second fins on a silicon substrate, the first and second fins being parallel to each other;
forming at least one fin portion, connecting the first and second fins for each pair of first and second fins;
forming a gate perpendicular to the plurality of pairs of first and second fins and over each at least one fin portion;
forming a first source and a first drain over each first fin at opposite sides of the gate;
forming a second source and a second drain over each second fin, separate from the first source and drain, at opposite sides of the gate; and
determining a resistance of the first and second source and first and second drain extension regions (Rex) utilizing two test modes, a first mode in which the on resistance (Ron1) satisfies Ron1=2 (Rex+Rch), and the second mode in which the on resistance (Ron2) satisfies Ron2=2 (Rex+Rch)+Rint, wherein Rch is the gate channel resistance, and Rint is the internal resistance along the fin portion,
wherein each of the first and second sources and first and second drains includes an extension region.

18. (canceled)

19. The method according to claim 17, wherein each first fin comprises first and second fin sections separated from each other, and each second fin comprises first and second fin sections separated from each other, and forming each at least one fin portion comprises:
forming a first fin portion connecting the first fin section of the first fin and the second fin section of the second fin;
forming a second fin portion crossing the first fin portion, connecting the second fin section of the first fin and the first fin section of the second fin; and
forming a third fin portion, in a v-shape, connecting the first fin section of the second fin and the second fin section of the second fin.

20. The method according to claim 19, further comprising determining a resistance of the first and second source and first and second drain extension regions (Rex) utilizing two test modes, a first mode in which the on resistance (Ron1) satisfies Ron1=3/2 (Rch+Rex), and the second mode in which the on resistance (Ron2) satisfies Ron2=Rch+2 Rex, wherein Rch equals the gate channel resistance.
